(19) United States
(12) Patent Application Publication
(10) Pub. No.: US 2019/0022788 A1
(43) Pub. Date: Jan. 24, 2019

(54) HEATING AND COOLING APPARATUS FOR BONDING MACHINE AND MANUFACTURING METHOD THEREOF

(71) Applicant: SHANGHAI MICRO ELECTRONICS EQUIPMENT (GROUP) CO., LTD., Shanghai (CN)

(72) Inventor: Jianjun ZHAO, Shanghai (CN)

(73) Assignee: SHANGHAI MICRO ELECTRONICS EQUIPMENT (GROUP) CO., LTD., Shanghai (CN)

(21) Appl. No.: 16/067,254

(22) PCT Filed: Dec. 23, 2016
(86) PCT No.: PCT/CN2016/111778

§ 371 Date: Jun. 29, 2018

(30) Foreign Application Priority Data
Dec. 30, 2015 (CN) 201511025791.4

(51) Int. Cl. B23K 9/16; B23K 9/007; B23K 35/30; B81C 3/00; H01L 21/67

(52) U.S. Cl. CPC B23K 9/16; B23K 9/007; B23K 35/3033; B23P 15/00; H01L 21/67092; H01L 21/67098; H01L 21/67248; B81C 3/001

(57) ABSTRACT

A heating and cooling arrangement of a bonder is disclosed which includes a heating-wire plate (1), a cooling-pipe plate (2), a heating wire (5), a cooling pipe (6) and a solder layer. The heating wire (5) and the cooling pipe (6) are welded in respective channels in the heating-wire plate (1) and the cooling-pipe plate (2) and uniformly welded together by the solder layer. The heating wire (5) is configured to connect to an external heating device, the cooling pipe (6) is configured to connect to an external cooling device. A method of fabricating such a heating and cooling arrangement of a bonder is also disclosed. In the bonder heating and cooling arrangement, the heating wire and the cooling pipe are uniformly welded together by the solder layer to form an integrated assembly with a smaller overall thickness, a shortened heat transfer path and increased cooling efficiency. This reduces the work load of a required vacuum pump, enhances the surface flatness of the component and increases bonding accuracy.

### TECHNICAL FIELD

The present invention relates to bonders and, in particular, to a heating and cooling arrangement of a bonder and a method of fabricating the arrangement, pertaining to the field of micro-electromechanical system (MEMS) manufacturing.

### BACKGROUND

Wafer bonding is a technique to bond wafers of different materials together and is important to three-dimensional processing of semiconductor devices. A wafer bonding process essentially involves wafer surface processing (cleaning, activation), alignment and bonding. After these steps, individual wafers are aligned and bonded together to form a three-dimensional structure. Bonding is not only employed for packaging in micro-electromechanical system (MEMS) technology but also constitutes part of three-dimensional device fabrication. It is involved in both front-end and back-end operations in the fabrication. A bonder is a device for bonding materials placed between two flat plates that can be heated. The materials are bonded to each other due to van der Waals forces, molecular forces or even atomic forces generated under an external condition such as an applied pressure, temperature or voltage. Therefore, the pressure and temperature that the two flat plates can provide to the materials to be bonded are considered as important metrics for evaluating the performance of the bonder.

A conventional bonder includes main plates each having a certain thickness and with respective rounded surfaces facing each other. Heating wires and cooling pipes are buried in channels slotted underneath the rounded surfaces. The channels are filled up with a braze material and a milling process is performed to ensure flatness of the rounded surfaces. Under pressurized and heated conditions, this apparatus, however, can only ensure consistent surface flatness at the non-channel portions and irregularities may occur at the channel portions. In addition, in order to prevent deformation of the main plates while taking into account the bearing capacity of each main plate after slotting on both sides thereof, they are each designed with a rather large thickness. This is however, unfavorable to the heating and cooling processes and requires a large vacuum chamber and hence a great work load of a vacuum pump for evacuating the chamber.

Further, a conventional welding process (e.g., that for welding the heating wires and cooling pipes in the channels as described above) is typically associated with the issue of incomplete degassing, and the residual air remaining in the main plates may survive the inspection and expand when heated during use, thus resulting in irregularities in surface flatness or even cracks in the wafers in severe scenarios.

### SUMMARY OF THE INVENTION

It is an objective of the present invention to provide a heating and cooling arrangement of a bonder, which is capable of faster heating and cooling with satisfactory surface flatness. It is also an objective of the present invention to provide a method for making such a heating and cooling arrangement, which is capable of complete degassing of welding joints.

To achieve these objectives, the heating and cooling arrangement provided in the present invention includes a heating-wire plate, a cooling-pipe plate, a heating wire, a cooling pipe and a solder layer. The heating wire and the cooling pipe are welded in respective channels in the heating-wire plate and the cooling-pipe plate and uniformly welded together by the solder layer. The heating wire is configured to connect to an external heating device, and the cooling pipe is configured to connect to an external cooling device.

Preferably, the external heating device is an electric heater.

Preferably, the external cooling device is filled with a cooling substance as a refrigerant.

Preferably, one of or each of the heating wire and the cooling pipe is a uniform spiral.

Preferably, the solder layer is made from a vacuum brazing solder.

Preferably, the vacuum brazing solder is a nickel-based solder.

Preferably, the heating and cooling arrangement has a thickness of from 22 mm to 25 mm.

Compared to the prior art, in this solution, the heating wire and the cooling pipe are uniformly welded together by the solder layer to form an integrated assembly with a smaller overall thickness, a shortened heat transfer path, an enlarged effective cooling area, increased cooling efficiency, a reduced process cycle and an augmented yield. In addition, a vacuum chamber in which bonding is carried out can be miniaturized, reducing the work load and time required for a vacuum pump to create a desired vacuum degree. Further, as each of the heating-wire and cooling-pipe plates is channeled at only one of its surfaces, with their other surfaces for contacting materials to be bonded, and since the channeled surfaces are welded together, the component has enhanced surface flatness and can thus provide a more uniform pressure. As a result, higher bonding accuracy is attained.

In order to achieve the above objectives, the method provided in the present invention includes the steps of:

1) placing and fixing by welding the heating wire and the cooling pipe in the channels in the heating-wire plate and the cooling-pipe plate, respectively;

2) disposing a vacuum brazing solder between surfaces of the heating wire plate and the cooling pipe plate and welding the surfaces together at edges thereof with an opening remaining in the edges;

3) heating and melting the vacuum brazing solder in a vacuum chamber, concurrently with a pressure being applied to allow a uniform distribution of the vacuum brazing solder between the heating wire and the cooling pipe and with the vacuum chamber being evacuated to completely remove an air present between the welded surfaces, followed by closing the opening by welding; and

4) finishing upper and lower surfaces of the heating and cooling arrangement.

Preferably, in step 1), the heating wire is fixed in the channel in the heating-wire plate by spot argon-arc welding and the cooling pipe is fixed in the channel in the cooling-pipe plate by spot argon-arc welding.

Preferably, in step 2), the surfaces are argon-arc welded together at the edges thereof.

Preferably, in step 2), two openings are remained.

Preferably, in step 3), the heating is carried out at a temperature of 1000-1040° C.

Preferably, in step 3), the heating is carried out for 0.5 hour.

Preferably, in step 3), during the application of the pressure for allowing a uniform distribution of the vacuum brazing solder between the heating wire and the cooling pipe, an excess of the vacuum brazing solder discharges from the opening.

Preferably, in step 4), the upper and lower surfaces of the heating and cooling arrangement are finished by a milling process.

Preferably, the vacuum brazing solder is a nickel-based solder.

Compared to the prior art, in this solution, through heating the solder disposed between the heating wire and the cooling pipe in a vacuum, making it uniformly distributed therebetween with an applied pressure and completely removing the air present therebetween, the problem of unsatisfactory flatness or cracking arising from the expansion of residual air during heating in a subsequent bonding process can be addressed. Additionally, finishing the upper and lower surfaces after the welding allows the surfaces to each have a planarity that can meet more critical requirements.

### BRIEF DESCRIPTION OF THE DRAWINGS

FIG. 1 is a structural schematic of a heating and cooling arrangement of a bonder according to a specific embodiment of the present invention.

FIG. 2 is a structural schematic of a heating wire according to a specific embodiment of the present invention.

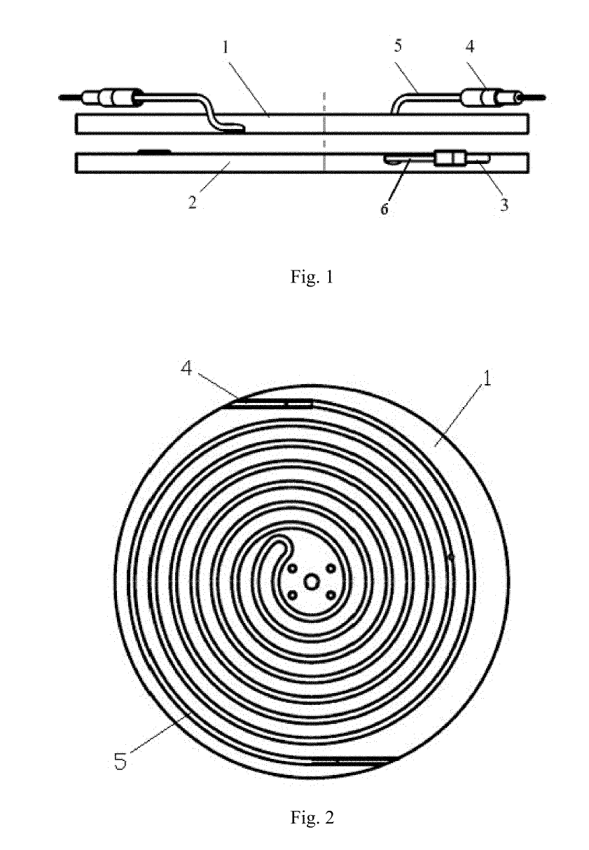

In FIG. 1: 1—heating-wire plate; 2—cooling-pipe plate; 3—cooling-pipe interface; 4—heater interface; 5—heating wire; 6—cooling pipe.

### DETAILED DESCRIPTION OF PREFERRED EMBODIMENTS

The present invention will be described in greater detail with reference to the accompanying drawings.

FIG. 1 shows an embodiment of a heating and cooling arrangement of a bonder according to the present invention, which includes a heating-wire plate 1, a cooling-pipe plate 2, a heating wire 5, a cooling pipe 6 and a solder layer. The heating wire 5 and the cooling pipe 6 are welded in respective channels in the heating-wire plate 1 and the cooling-pipe plate 2, and the heating wire 5 and the cooling pipe 6 are uniformly welded together by the solder layer. The heating wire 5 is connected to an external heating device via a heater interface 4, while the cooling pipe 6 is connected to an external cooling device via a cooling-pipe interface 3. The external heating device may be an electric heater. The external cooling device may be filled with a cooling substance as a refrigerant. Each of the heating wire 5 and the cooling pipe 6 may be a uniform spiral. The solder layer may be a vacuum brazing solder. The vacuum brazing solder may be a nickel-based solder. The heating and cooling arrangement may have a thickness of 22 mm to 25 mm.

With this design, the heating wire 5 and the cooling pipe 6 are uniformly welded together by the solder layer to form an integrated assembly with a smaller overall thickness, a shortened heat transfer path, an enlarged effective cooling area, increased cooling efficiency, a reduced process cycle and an augmented yield. In addition, a vacuum chamber in which bonding is carried out can be miniaturized, reducing the work load and time required for a vacuum pump to create a desired vacuum degree.

FIG. 2 shows an embodiment of the heating wire in the heating and cooling arrangement according to the present invention. The heating wire 5 and/or the cooling pipe 6 may be uniform spiral(s). With this design, uniform heat conduction can be attained, resulting in uniform temperature distributions across the heating-wire plate 1 and the cooling-pipe plate 2, which is favorable to bonding accuracy.

In practical use, the cooling-pipe plate 2 of one such heating and cooling arrangement is connected to a control pipe of the bonder so that it can be moved and applied with a pressure under the action of the control pipe, while the cooling-pipe plate 2 of another such heating and cooling arrangement is connected to a base of the bonder. After two aligned wafers are placed by a wafer loader of the bonder onto the surface of the heating-wire plate 1 of the lower heating and cooling arrangement, a vacuum is created and a pressure is applied on the wafers by moving the upper heating and cooling arrangement under the control of the bonder so that the surface of its heating-wire plate 1 comes into contact with and presses against the wafers. At the same time, the external electric heater is activated and transfers heat via the heating wires 5 in connection therewith to the upper and lower heating-wire plates 1 so that the wafers are heated by the two heating-wire plates 1 and bonded together. After the completion of the bonding, the wafers are removed and the refrigerant is circulated within the cooling pipes 6 to rapidly cool the heating-wire plates 1. As a result, the process cycle is shortened with an increased yield.

With combined reference to FIGS. 1 and 2, the present invention also provides a method of fabricating the heating and cooling arrangement as described above, which includes the steps as detailed below.

In Step 1, the heating wire 5 and the cooling pipe 6 are placed and welded in the respective channels in the heating-wire plate 1 and the cooling-pipe plate 2. Specifically, the heating wire 5 and the cooling pipe 6 may be spot argon-arc welded in the respective channels in the heating-wire plate 1 and the cooling-pipe plate 2.

In Step 2, a vacuum brazing solder is disposed between the surfaces of the heating-wire plate and the cooling-pipe plate and the surfaces are argon arc welded together at their circumferential edges with an opening remaining in the circumferential edge. Specifically, the vacuum brazing solder may be a nickel-based solder.

In Step 3, the vacuum brazing solder is heated and melted in a vacuum chamber, concurrently with a pressure being applied to allow a uniform distribution of the vacuum brazing solder between the heating wire 5 and the cooling pipe 6 and with the vacuum chamber being evacuated to completely remove the air present between the welded surfaces, followed by closing the opening by welding. The pressure in the vacuum chamber may be reduced to 0.01 Pa to 0.001 Pa, and the heating may be conducted at a temperature of 1000-1040° C. for 0.5 hour. Under these conditions, the vacuum brazing solder can be completely melted. Of course, during the process, the vacuum chamber may be evacuated to completely remove the air therein. Preferably, under the action of the pressure, an excess of the vacuum brazing solder discharges from the opening. Subsequent to the application of the pressure and the complete removal of the air, the opening may be completely closed by argon-arc welding.

In Step 4, the upper and lower surfaces of the heating and cooling arrangement are finished. The surfaces may be finished using a milling process so as to achieve a planarity of 0.01 mm.

Preferably, the number of the openings may be two. The two openings may locate on opposing sides of the circumferential edge of the welding surfaces of the heating wire 5 and the cooling pipe 6.

A specific example of the method of fabricating the heating and cooling arrangement is set forth below.

At first, the heating wire 5 and the cooling pipe 6 are placed in the respective channels in the heating-wire plate 1 and the cooling-pipe plate 2, then the heating wire 5 and the cooling pipe 6 are argon-arc welded in the respective channels in the heating-wire plate 1 and the cooling-pipe plate 2. A nickel-based solder is then disposed between the surfaces of the plates in which the channels are formed and the surfaces are argon arc welded together at their circumferential edges with two opposing openings remaining in the weld joint. The assembly is then placed in a vacuum chamber evacuated to a pressure of 0.01 Pa and heated at 1040° C. for 0.5 hour so that the vacuum brazing solder is melted. A pressure is then applied to allow a uniform distribution of the vacuum brazing solder between the heating wire and the cooling pipe, concurrently with the air remaining between the surface being completely removed and an excess of the vacuum brazing solder discharging from the openings. Following this, the openings are completely closed by argon-arc welding. After the completion of the welding, the upper and lower surfaces of the heating and cooling arrangement are finished by milling process so as to achieve a planarity of 0.01 mm.

According to the present invention, through heating the vacuum brazing solder disposed between the heating wire 5 and the cooling pipe 6 in a vacuum, making the vacuum brazing solder uniformly distributed between the heating wire and the cooling pipe with an applied pressure and completely removing the air present therebetween, the problem of unsatisfied flatness or cracking arising from the expansion of residual air during heating in a subsequent bonding process can be addressed. Additionally, finishing the upper and lower surfaces after the welding allows the surfaces to each have a planarity that can meet more critical requirements.

What is claimed is:

1. A heating and cooling arrangement of a bonder, comprising a heating-wire plate, a cooling-pipe plate, a heating wire, a cooling pipe and a solder layer, the heating wire and the cooling pipe being welded in respective channels in the heating-wire plate and the cooling-pipe plate and uniformly welded together by the solder layer, the heating wire configured to connect to an external heating device, the cooling pipe configured to connect to an external cooling device.

2. The heating and cooling arrangement of a bonder according to claim 1, wherein the external heating device is an electric heater.

3. The heating and cooling arrangement of a bonder according to claim 1, wherein the external cooling device is filled with a cooling substance as a refrigerant.

4. The heating and cooling arrangement of a bonder according to claim 1, wherein one of or each of the heating wire and the cooling pipe is a uniform spiral.

5. The heating and cooling arrangement of a bonder according to claim 1, wherein the solder layer is made from a vacuum brazing solder.

6. The heating and cooling arrangement of a bonder according to claim 5, wherein the vacuum brazing solder is a nickel-based solder.

7. The heating and cooling arrangement of a bonder according to claim 1, wherein the heating and cooling arrangement of a bonder has a thickness of from 22 mm to 25 mm.

8. A method of fabricating the heating and cooling arrangement of a bonder as defined in claim 1, comprising the steps of:
1) placing and fixing by welding the heating wire and the cooling pipe in the channels in the heating-wire plate and the cooling-pipe plate, respectively;
2) disposing a vacuum brazing solder between surfaces of the heating wire plate and the cooling pipe plate and welding the surfaces together at edges thereof with an opening remaining in the edges;
3) heating and melting the vacuum brazing solder in a vacuum chamber, concurrently with a pressure being applied to allow a uniform distribution of the vacuum brazing solder between the heating wire and the cooling pipe and with the vacuum chamber being evacuated to completely remove an air present between the welded surfaces, followed by closing the opening by welding; and
4) finishing upper and lower surfaces of the heating and cooling arrangement.

9. The method according to claim 8, wherein in step 1), the heating wire is fixed in the channel in the heating-wire plate by spot argon-arc welding and the cooling pipe is fixed in the channel in the cooling-pipe plate by spot argon-arc welding.

10. The method according to claim 8, wherein in step 2), the surfaces are argon-arc welded together at the edges thereof.

11. The method according to claim 8, wherein in step 2), two openings are remained.

12. The method according to claim 8, wherein in step 3), the heating is carried out at a temperature of 1000-1040° C.

13. The method according to claim 8, wherein in step 3), the heating is carried out for 0.5 hour.

14. The method according to claim 8, wherein in step 3), during the application of the pressure for allowing a uniform distribution of the vacuum brazing solder between the heating wire and the cooling pipe, an excess of the vacuum brazing solder discharges from the opening.

15. The method according to claim 8, wherein in step 4), the upper and lower surfaces of the heating and cooling arrangement are finished by a milling process.

16. The method according to claim 8, wherein the vacuum brazing solder is a nickel-based solder.
